(19) United States
(12) Patent Application Publication
(10) Pub. No.: US 2017/0054027 A1
(43) Pub. Date: Feb. 23, 2017

(54) WIMPY FINFET DEVICES AND METHODS FOR FABRICATING THE SAME

(71) Applicant: BROADCOM CORPORATION, Irvine, CA (US)

(72) Inventor: Qing Liu, Watervliet, NY (US)

(21) Appl. No.: 14/831,106

(22) Filed: Aug. 20, 2015

Related U.S. Application Data
(60) Provisional application No. 62/206,713, filed on Aug. 18, 2015.

(51) Int. Cl. H01L 29/78; H01L 29/66

(52) U.S. Cl. CPC H01L 29/7855; H01L 29/66795; H01L 29/66545

(57) ABSTRACT

A wimpy finFET device and method for fabricating the same is described. The device is fabricated by forming a mandrel that is non-perpendicular to long axes of the underlying fin(s) (i.e., the mandrel is formed at a non-quadrantal angle with respect to the long axes). Spacers formed on the sidewalls of the angled mandrel are thus also formed non-perpendicular to the long axes. The spacers are used to pattern underlying layer(s) down to the underlying fin(s) to form the gates for the device. Because the patterned layer(s) are also formed at a non-quadrantal angle, the width of the patterned layer(s) over the underlying fin(s) is greater than would be if the patterned layer(s) were formed at, e.g., a right angle with respect to the long axis. The desired gate length and gate pitch is respectively achieved by determining the angle at which the mandrel is formed and the mandrel width.

### CROSS-REFERENCE TO RELATED APPLICATION(S)

This application claims the benefit of U.S. Provisional Application No. 62/206,713, filed Aug. 18, 2015, the entirety of which is incorporated by reference herein.

### BACKGROUND

Technical Field

Embodiments described herein relate to semiconductor devices and more particularly to fin field-effect transistors (finFETs).

Description of Related Art

Transistors are fundamental device elements of modern digital processors and memory devices and have found applications in high-power electronics. Currently, there are a variety of transistor designs or types that may be used for different applications. Various transistor types include, for example, bipolar junction transistors (BJT), junction field-effect transistors (JFET), metal-oxide-semiconductor field-effect transistors (MOSFET), vertical channel or trench field-effect transistors, and superjunction or multi-drain transistors.

The demand for increased performance and shrinking geometry integrated circuits (ICs) has led to the introduction of multi-gate devices. These multi-gate devices include multi-gate fin-type transistors, also referred to as fin field-effect transistor (finFET) devices.

Depending on the product application, a mix of first finFET device(s) having a nominal gate length (i.e., nominal finFET devices) and second finFET device(s) having a different gate length than the nominal gate length (i.e., wimpy finFET devices) may be needed. Conventionally, in order to manufacture finFETs in accordance with 10 nm and 7 nm manufacturing processes, gate patterning is done using a sidewall image transfer (SIT) technique. In accordance with these processes, two spacers are formed for each of the finFETs being manufactured.

The thickness (or width) of the spacers define the length of the gates for the finFET being manufactured. In order to modify the gate length for a particular finFET so that it is not the nominal gate length (i.e., to create a wimpy finFET device), the spacer thicknesses for that particular finFET are subsequently reduced or increased (depending on the desired application).

For example, FIGS. 1A-1D show an example of a conventional SIT technique where the spacer thickness is reduced to form a wimpy finFET device. As shown in FIG. 1A, a mandrel 102 and a mandrel 104 are formed on a substrate 106 having one or more silicon-based layers. Mandrels 102 and 104 may be formed by depositing and patterning a silicon-based layer of material using known deposition, photolithography and etching tools and techniques. As further shown in FIG. 1A, a layer of silicon-based spacer material 110 is conformably deposited over mandrels 102 and 104 and substrate 106. Spacer material 110 may be comprised of a variety of materials, such as, for example silicon nitride, silicon dioxide, etc. As shown in FIG. 1B, an etching process is performed to define a spacer 112A and a spacer 112B adjacent to mandrel 102 and spacers 114A and 114B adjacent to mandrel 104. As shown in FIG. 1C, mandrels 102 and 104 are removed, for example, by a selective etching process that leaves spacers 112A, 112B, 114A, and 114B, which are used as masks for a subsequent etching process performed on substrate 106 to form finFET devices.

As shown in FIG. 1D, spacers 114A and 114B (which will be used to form a nominal finFET device) are covered by a protective mask 120, and an etching process is performed on spacers 112A and 112B (which will be used to form a wimpy finFET device) to reduce the thickness thereof. As further shown in FIG. 1D, the reduction in thickness of spacers 112A and 112B enables the formation of a wimpy finFET device having a gate length of X, which is less than a gate length of Y for a nominal finFET device.

However, the introduction of protective mask 120 when forming wimpy finFET devices is very challenging, and introduces a significant amount of process complexity and variation. Other known prior art techniques for reducing or increasing spacer thickness suffer from similar disadvantages.

### BRIEF SUMMARY

Wimpy finFET devices and methods for fabricating the same are described, substantially as shown in and/or described in connection with at least one of the figures, as set forth more completely in the claims.

### BRIEF DESCRIPTION OF THE DRAWINGS/FIGURES

The accompanying drawings, which are incorporated herein and form a part of the specification, illustrate embodiments and, together with the description, further serve to explain the principles of the embodiments and to enable a person skilled in the pertinent art to make and use the embodiments.

FIG. 1A-1D collectively illustrate a conventional sidewall image transfer (SIT) technique used to form a plurality of spacers.

FIG. 2A shows a top view of a structure that comprises a substrate having one or more fins formed thereon in accordance with an embodiment.

FIG. 2B shows a cross-sectional view of the structure of FIG. 2A.

FIG. 2C shows a cross-sectional view of a structure fabricated by forming a dummy gate stack layer, a hardmask layer, and a mandrel layer on the structure shown in FIGS. 2A and 2B in accordance with an embodiment.

FIG. 2D shows a top view of a structure fabricated by forming mandrels on the hardmask layer of the structure shown in FIG. 2C in accordance with an embodiment.

FIG. 2E shows a cross-sectional view of the structure of FIG. 2D.

FIG. 2F shows a cross-sectional view of a structure fabricated by forming a spacer material layer over the structure shown in FIGS. 2D and 2E in accordance with an embodiment.

FIG. 2G shows a top view of a structure fabricated by forming spacers adjacent to the mandrels and on top of the hardmask layer of the structure shown in FIG. 2F in accordance with an embodiment.

FIG. 2H shows a cross-sectional view of the structure of FIG. 2G.

FIG. 2I shows a top view of a structure fabricated by removing the mandrels from the structure shown in FIGS. 2G and 2H in accordance with an embodiment.

FIG. 2J shows a cross-sectional view of the structure shown in FIG. 2I.

FIG. 2K shows a cross-sectional view of a structure fabricated by patterning the hardmask layer and dummy gate stack layer of the structure shown in FIGS. 2I and 2J in accordance with an embodiment.

FIG. 2L shows a top view of a structure fabricated by removing the spacers from the structure of FIG. 2K, thereby forming gates for a nominal finFET device and a wimpy finFET device in accordance with an embodiment.

FIG. 2M shows a cross-sectional view of the structure shown in FIG. 2L.

FIG. 3 shows a flowchart of an example process for fabricating a wimpy finFET device in accordance with an embodiment.

FIG. 4 shows a flowchart of an example process for forming a mandrel in accordance with an embodiment.

FIG. 5 shows a flowchart of an example process for forming a mandrel in accordance with another embodiment.

FIG. 6 shows a flowchart of an example process for forming a mandrel in accordance with yet another embodiment.

FIG. 7 shows a flowchart of an example process for forming a first spacer and a second spacer in accordance with an embodiment.

FIG. 8 shows a flowchart of an example process for forming a first gate and a second gate in accordance with an embodiment.

The features and advantages of the subject matter of the present application will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### I. Introduction

The present specification discloses numerous example embodiments. The scope of the present patent application is not limited to the disclosed embodiments, but also encompasses combinations of the disclosed embodiments, as well as modifications to the disclosed embodiments.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

Moreover, descriptive terms used herein such as “about,” “approximately,” and “substantially” have equivalent meanings and may be used interchangeably.

Numerous exemplary embodiments are now described. Any section/subsection headings provided herein are not intended to be limiting. Embodiments are described throughout this document, and any type of embodiment may be included under any section/subsection. Furthermore, it is contemplated that the disclosed embodiments may be combined with each other in any manner.

### II. Example Embodiments

A wimpy finFET device and method for fabricating the same is described herein. According to the described techniques, a wimpy finFET device is fabricated by forming a mandrel that is non-perpendicular to long axes and/or short axes of underlying fin(s) formed over a substrate (i.e., the mandrel is formed at a non-quadrantal angle (an angle that is not 0 degrees, 90 degrees, 180 degrees, 270 degrees) with respect to the long axes and/or the short axes of the underlying fin(s)). Spacers formed on the sidewall of the angled mandrel are thus also formed non-perpendicular to the long axes and/or the short axes of the underlying fin(s). The spacers are used to pattern one or more underlying layers (e.g., a hardmask layer and dummy gate stack layer) down to the underlying fin(s). The resulting structures are the gates for the wimpy finFET device. Because the underlying, patterned layers are also formed at a non-quadrantal angle, the width of the patterned layer(s) over the underlying fin(s) is greater than would be if the patterned layer(s) were formed at, for example, a right angle with respect to the long axes. The greater width corresponds to greater gate length. The desired gate length for the gates may be achieved by determining the angle at which the mandrel is formed. The desired gate-to-gate distance (or “gate pitch”) may be achieved by determining the mandrel width (or thickness) at which the mandrel is formed.

For instance, a method is described herein. In accordance with the method, at least one fin is formed on a substrate. The at least one fin extends perpendicularly from a surface of the substrate, and the at least one fin has a first axis and a second axis that is perpendicular to the first axis. A dummy gate stack layer and a hardmask layer are formed over the at least one fin and at least a portion of the substrate. A mandrel is formed on the hardmask layer. The mandrel extends along the hardmask layer in a direction that is non-perpendicular to at least the first axis of the at least one fin. A first spacer is formed on a first side of the mandrel, and a second spacer is formed on a second side of the mandrel that opposes the first side. The first and second spacers extend along the hardmask layer in a direction that is non-perpendicular to at least the first axis of the at least one fin. The mandrel is removed. A first gate and a second gate are formed that each comprise a portion of the dummy gate stack layer and the hardmask layer. The first gate has a gate length that corresponds approximately to a width of the first spacer along the first axis of the at least one fin, and the second gate has a gate length that corresponds approximately to a width of the second spacer along the first axis of the at least one fin.

A wimpy semiconductor device is also described herein. The wimpy semiconductor device includes at least one fin on a substrate. The at least one fin extends perpendicularly from a surface of the substrate, and the at least one fin has a first axis and a second axis that is perpendicular to the first axis. The wimpy semiconductor device also includes a first gate and a second gate that each comprise a dummy gate stack layer and a hardmask layer formed over the at least one fin. The dummy gate stack layer and the hardmask layer extend along the at least one fin in a direction that is non-perpendicular to at least the first axis of the at least one fin and is non-perpendicular to at least the second axis of the at least one fin.

Another method is described herein. In accordance with the method, a plurality of cuboid-shaped fins are formed on a substrate. The plurality of cuboid-shaped fins extend perpendicularly from a surface of the substrate. Each cuboid-shaped fin has a long axis and a short axis that is perpendicular to the long axis. The long axes of the cuboid-shaped fins are roughly parallel to one another. A dummy gate stack layer and a hardmask layer are formed over the plurality of cuboid-shaped fins and at least a portion of the substrate. A mandrel is formed on the hardmask layer. The mandrel extends along the hardmask layer in a direction that is non-perpendicular to the long axis of at least one of the cuboid-shaped fins. A first spacer is formed on a first sidewall of the mandrel and a second spacer is formed on a second sidewall of the mandrel. The first and second spacers extend along the hardmask layer in a direction that is non-perpendicular to the long axis of at least one of the cuboid-shaped fins. The mandrel is removed. A first gate and a second gate are formed that each comprise a portion of the dummy gate stack layer and the hardmask layer. The first gate has a gate length that corresponds approximately to a width of the first spacer along the long axis of at least one of the cuboid-shaped fins, and the second gate has a gate length that corresponds approximately to a width of the second spacer along the long axis of at least one of the cuboid-shaped fins.

These and further embodiments are described in detail in the following section.

### III. Example Wimpy Semiconductor Device

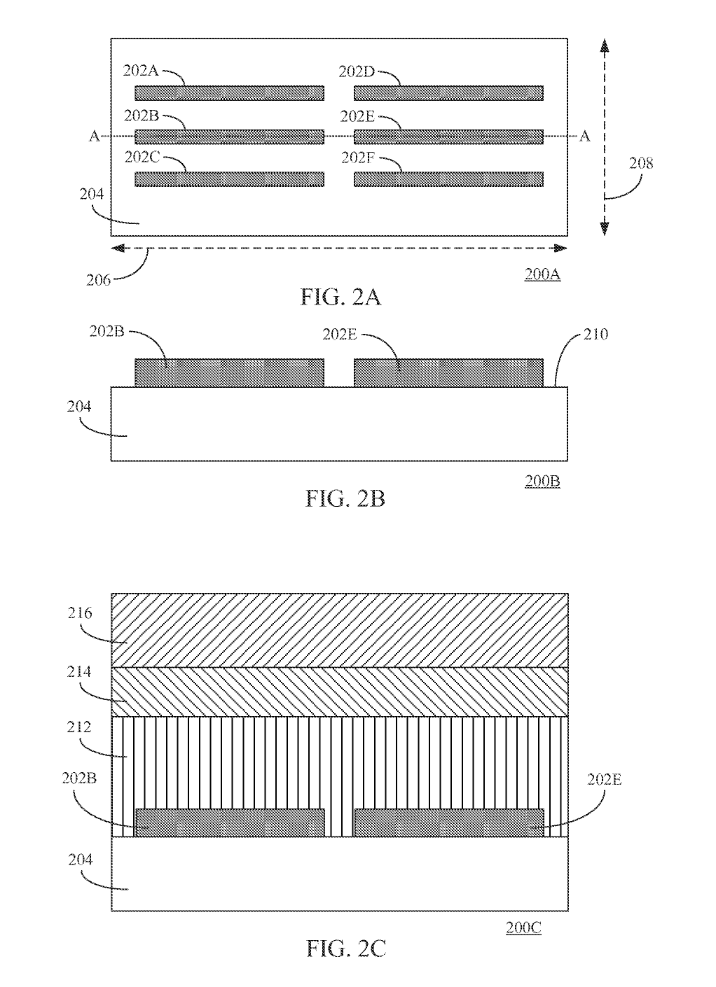

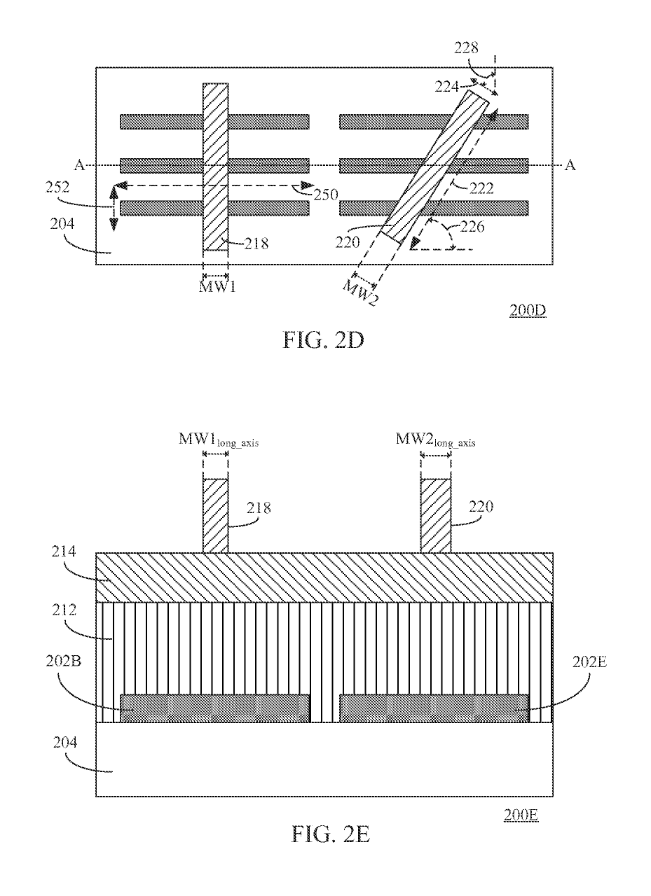

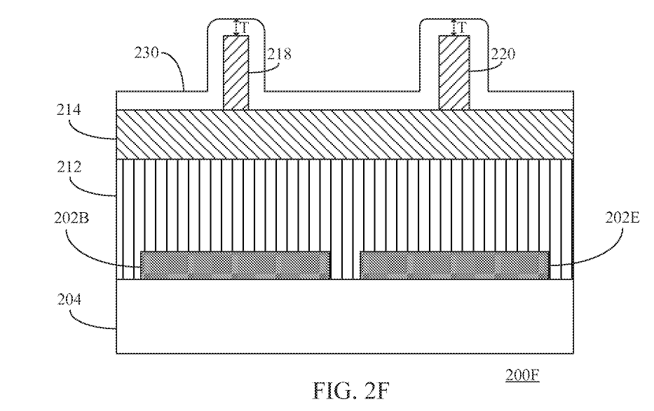

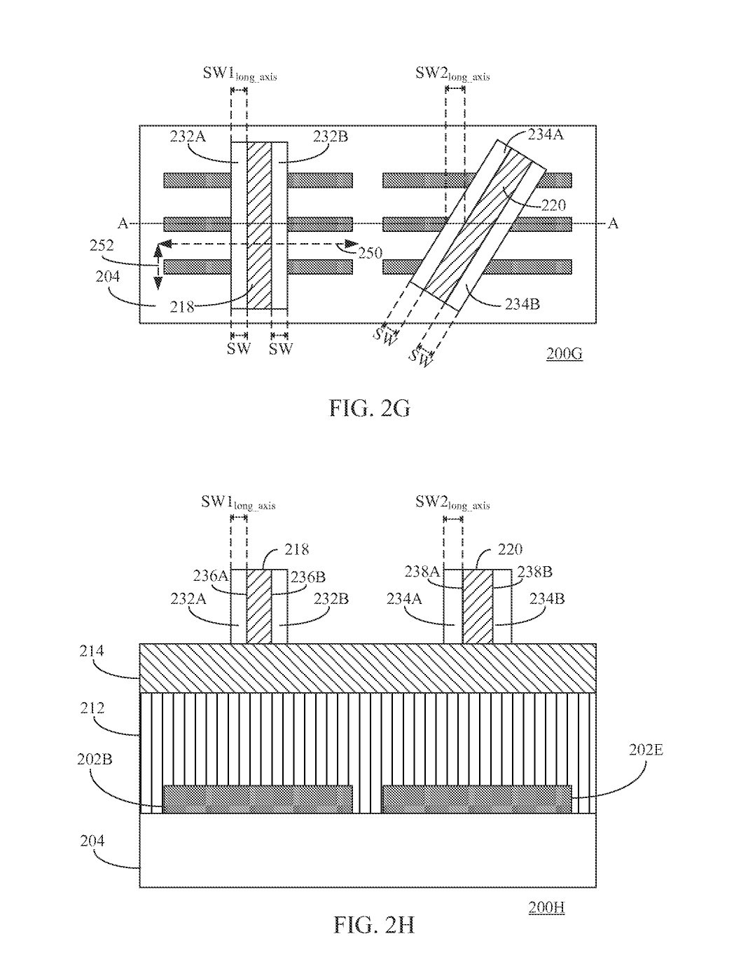

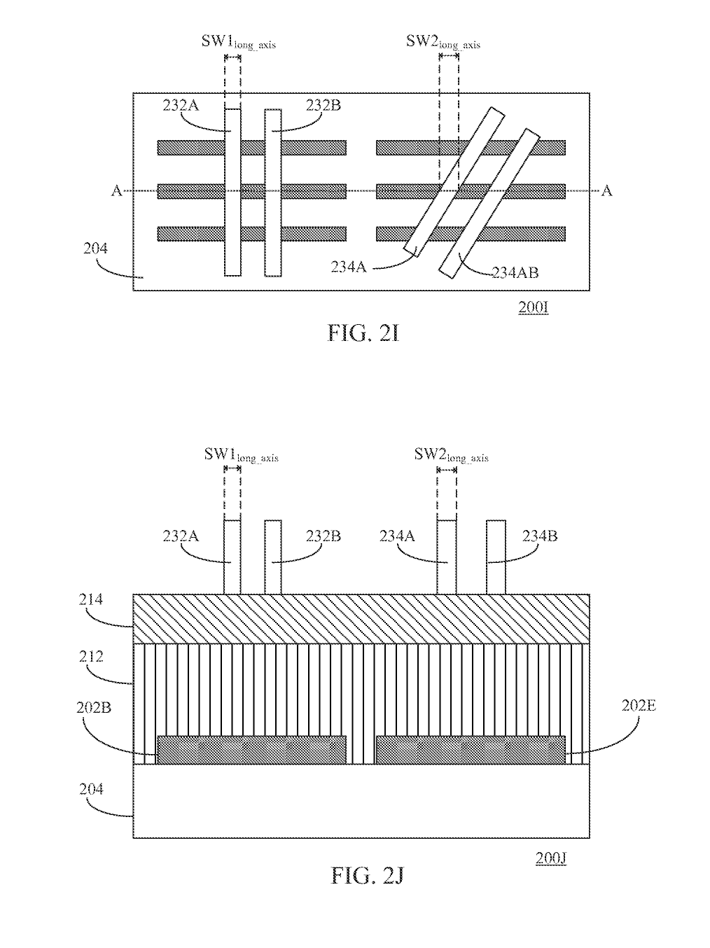

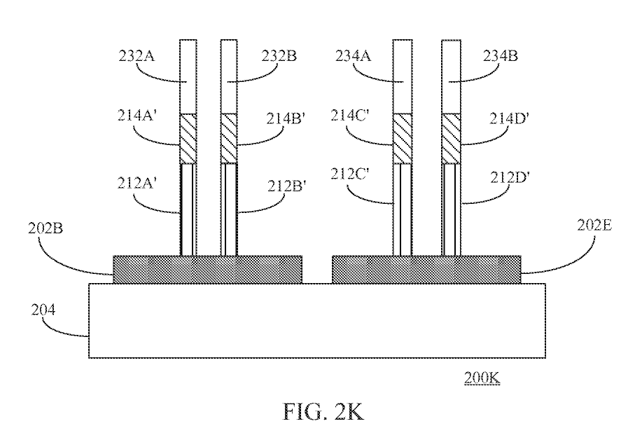

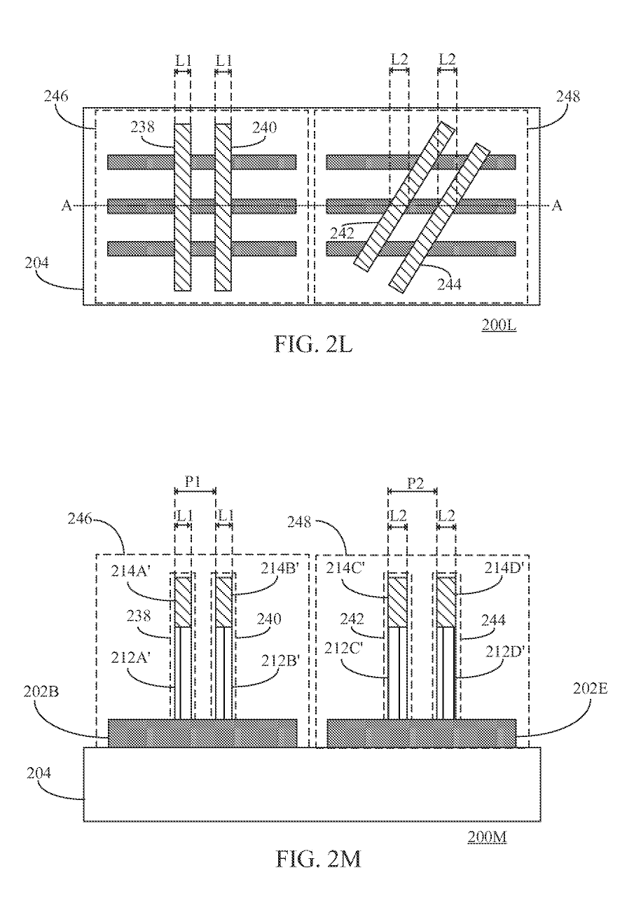

FIGS. 2A-2M collectively and schematically illustrate steps for forming a nominal finFET device and a wimpy finFET device in accordance with an embodiment. FIG. 2A shows a top view 200A of a structure that comprises a substrate 204 having one or more fins 202A, 202B, 202C, 202D, 202E, and 202F formed thereon. FIG. 2B is a cross-sectional view 200B of the structure of FIG. 2A along the line A-A in accordance with an embodiment. FIG. 2C is a cross-sectional view 200C of a structure fabricated by forming a dummy gate layer 212, a hardmask layer 214, and a mandrel layer 216 over substrate 204 and fin(s) 202A-202F in accordance with an embodiment. FIG. 2D shows a top view 200D of a structure fabricated by forming a mandrel 218 and a mandrel 220 on hardmask layer 214 of the structure shown in FIG. 2C in accordance with an embodiment. FIG. 2E is a cross-sectional view 200E of the structure of FIG. 2D along the line A-A in accordance with an embodiment. FIG. 2F is a cross-sectional view 200F of a structure fabricated by forming a spacer material layer 230 over hardmask layer 214 and mandrels 218 and 220 of the structure shown in FIGS. 2D and 2E in accordance with an embodiment. FIG. 2G is a top view 200G of a structure fabricated by forming a spacer 232A, a spacer 232B, a spacer 234A, and a spacer 234B adjacent to mandrels 218 and 220 and on top hardmask layer 214 of the structure shown in FIG. 2F in accordance with an embodiment. FIG. 2H is a cross-sectional view 200H of the structure of FIG. 2G along the line A-A in accordance with an embodiment. FIG. 2I is a top view 200I of a structure fabricated by removing mandrels 218 and 220 from the structure shown in FIGS. 2G and 2H in accordance with an embodiment. FIG. 2J is a cross-sectional view 200J of the structure shown in FIG. 2I along the line A-A in accordance with an embodiment. FIG. 2K is a cross-sectional view 200K of a structure fabricated by patterning hardmask layer 214 and dummy gate stack layer 212 of the structure shown in FIGS. 2I and 2J in accordance with an embodiment. FIG. 2L shows a top view of a structure fabricated by removing spacers 232A, 232B, 234A, and 234B from the structure of FIG. 2K, thereby forming a gate 238, a gate 240, a gate 242, and a gate 244 for a nominal finFET device 246 and a wimpy finFET device 248, respectively, in accordance with an embodiment. FIG. 2M is a cross-sectional view 200M of the structure shown in FIG. 2L along the line A-A in accordance with an embodiment.

As shown in FIGS. 2A and 2B, one or more fin-like structures (referred herein as “fins”) 202A-202F are formed on substrate 204. Each of fin(s) 202A-202F have a length extending along a first axis of substrate 204 (e.g., long axis 206), a width extending along a second axis of substrate 204 (e.g., short axis 208), and a height extending perpendicularly from a surface 210 of substrate 204 (as shown in FIG. 2B). Each of fin(s) 202A-202F may comprise one or more source and/or drain regions (not shown) that are formed in, on, and/or surrounding each of fin(s) 202A-202F. Fin(s) 202A-202F may be comprised of silicon or a silicon-based material, such as, but not limited to, silicon-germanium. Alternatively, fin(s) 202A-202F may be comprised of other elementary semiconductors, such as, but not limited to, germanium, gallium arsenic, gallium phosphide, indium phosphide, indium arsenide, and/or indium antimonide. Fin(s) 202A-202F may be formed using known deposition, photolithography and/or etching tools and techniques. As will be described below, fin(s) 202A-202C are used to form a nominal finFET device, and fin(s) 202D-202F are used to form a wimpy finFET device. The number of fin(s) define the width for the finFET device being manufactured, which in turn, determines the amount of current that flows through the finFET device. In particular, the amount of current that flows through a finFET device increases as the width (or number of fin(s)) increases. Accordingly, while FIG. 2A shows three fins per finFET device, any number of fins (e.g., 1, 2, 3, etc.) may be used to form a finFET device depending on the particular application. It also noted that while fin(s) 202A-202F are shown as being substantially cuboid-shaped, fin(s) 202A-202F may be of any elongated three-dimensional shape.

Substrate 204 may be comprised of silicon or a silicon-based material. In accordance with an embodiment, substrate 204 is a silicon-on-insulator (SOI) substrate. In accordance with such an embodiment, substrate 204 is comprised of a silicon-based material, such as, but not limited to, silicon dioxide. In accordance with another embodiment, substrate 204 is a bulk substrate. In accordance with such an embodiment, substrate 204 is comprised of silicon. It is noted that while substrate 204 is shown as being rectangular, substrate 204 may be of any shape, including, but not limited to, circular, square, etc. It is further noted that substrate 204 may be a portion of a larger substrate and that any number of nominal finFET devices and wimpy finFET devices may be formed on such a substrate.

Next, as shown in FIG. 2C, dummy gate stack layer 212 is formed over fin(s) 202A-202F and of substrate 204. Dummy gate stack layer 212 may be comprised of a silicon-based material, such as, but not limited to, polysilicon. Dummy gate stack layer 212 may be formed using known deposition, photolithography and/or etching tools and techniques.

As also shown in FIG. 2C, hardmask layer 214 is formed over dummy gate stack layer 212. Hardmask layer 214 may serve to protect dummy gate stack layer 212 during subsequent patterning steps performed for mandrel formation, as described below with respect to FIGS. 2D and 2E. Hardmask layer 214 may be comprised of a silicon-based material, such as, but not limited to, silicon nitride, or other materials, such as, but not limited to, hafnium oxide or tantalum nitride. Hardmask layer 214 may be formed using known deposition techniques, such as, but not limited to chemical vapor deposition (CVD).

It is noted that while FIG. 2C depicts dummy gate stack layer 212 as being formed completely over substrate 204, it is noted that dummy gate stack layer 212 may be formed over a portion of substrate 204 such that certain portions of substrate 204 are left exposed in accordance with one or more embodiments.

As further shown in FIG. 2C, mandrel (or SIT) layer 216 is formed over hardmask layer 214. Mandrel layer 216 may be comprised of a silicon-based material, such as, but not limited to, amorphous silicon, polysilicon, silicon dioxide, etc., or other materials, such as, but not limited to, hafnium oxide or tantalum nitride. Mandrel layer 216 may be formed using known deposition techniques, such as, but not limited to, CVD or physical vapor deposition (PVD).

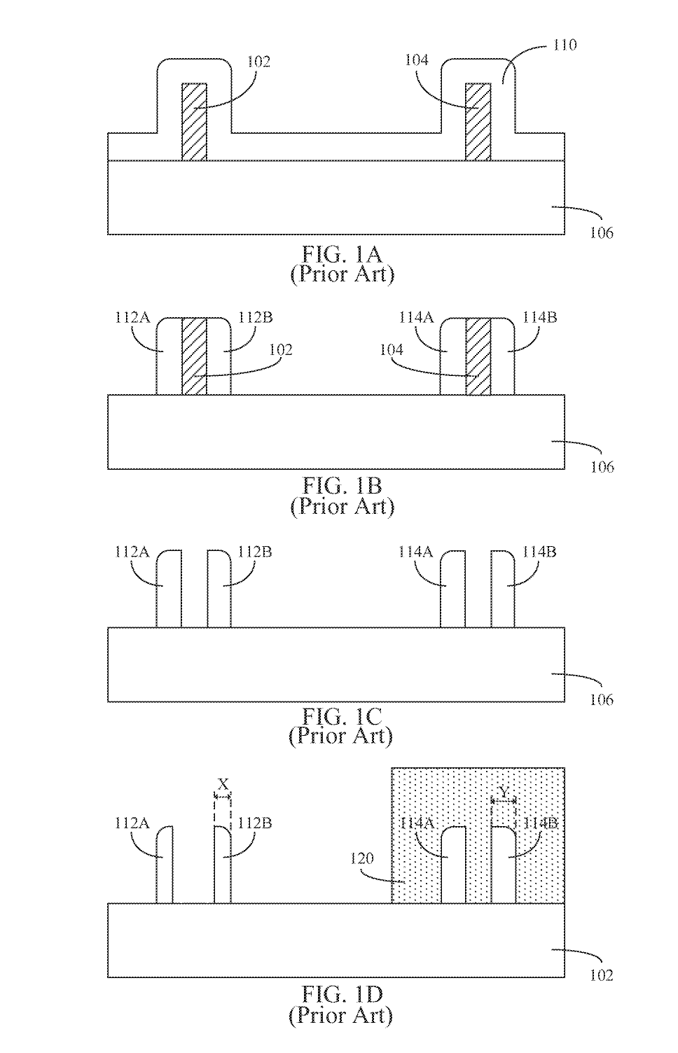

Next, as shown in FIGS. 2D and 2E, mandrels 218 and 220 are formed from mandrel layer 216. As shown in FIG. 2D, mandrel 218 is formed such that it has a length extending along a short axis 252 of each of fin(s) 202A-202F and such that it is formed across underlying fin(s) 202A-202C (dummy gate stack layer 212 and hardmask layer 214 are rendered transparent in FIG. 2D for ease of illustration), a width (MW1) extending along a long axis 250 of each of fin(s) 202A-202F, and a height extending perpendicularly from hardmask layer 214 (as shown in FIG. 2E). Mandrel 220 is formed such that it has a length extending along a direction that is non-perpendicular and non-parallel to short axis 252 and long axis 250 and such that it is formed across underlying fin(s) 202D-202F, a width (MW2) extending along a direction that is non-perpendicular and non-parallel to short axis 252 and long axis 250, and a height extending perpendicularly to hardmask layer 214 (as shown in FIG. 2E). Long axis 252 of each of fin(s) 202A-202F are roughly parallel to one another, and short axis 252 of each of fin(s) 202A-202F are roughly parallel to one another. Mandrel 220 is formed at a first non-zero angle 226 with respect to a long axis 222 of mandrel 220 and long axis 250, and formed at a second non-zero angle 228 with respect to a short axis 224 of mandrel 220 and short axis 252. Angles 226 and 228 at which mandrel 220 is formed determine the width of mandrel 220 over underlying fin(s) 202D-202F along long axis 250. In particular, as angles 226 and 228 decrease (i.e., as mandrel 220 is closer to being parallel with long axis 250), the width of mandrel 220 over underlying fin(s) 202D-202F along long axis 250 increases. For example, as shown in FIGS. 2D and 2E, mandrel 218 (which is formed perpendicularly to long axis 250 and parallel to short axis 252, thereby having angles of zero) has a width MW1_{long}_{_}ₐₓᵢₛ (which is equal to MW1) over underlying fin(s) 202A-202C along long axis 250, whereas mandrel 220, which is formed at approximately 35 degrees with respect to long axis 250 and short axis 252, has a width MW2_{long}_{_}ₐₓᵢₛ over underlying fin(s) 202D-202F along long axis 250, where MW2_{long}_{_}ₐₓᵢₛ is longer than MW1_{long}_{_}ₐₓᵢₛ. As will be described below, forming angled mandrels enable gate formation for wimpy finFET device(s) to be performed without an additional masking step as described above with reference to FIG. 1D.

Mandrels 218 and 220 may be formed separately or simultaneously and may be formed such that mandrels 218 and 220 have the same or different width. Mandrels 218 and 220 may be formed using photolithography (e.g., e-beam lithography) and/or etching (e.g., reactive-ion etching (RIE)).

Next, as shown in FIG. 2F, spacer material layer 230 is conformably deposited over mandrels 218 and 220 and hardmask layer 214 with a substantially uniform thickness T. Spacer material layer 230 may be comprised of a silicon-based material, such as, but not limited to, silicon nitride, silicon dioxide, etc. Spacer material layer 230 may be formed using known deposition techniques.

Next, as shown in FIGS. 2G and 2H, spacers 232A, 232B, 234A, and 234B are formed from spacer material layer 230 (dummy gate stack layer 212 and hardmask layer 214 are rendered transparent in FIG. 2G for ease of illustration). In particular, spacers 232A and 232B are formed on opposing first and second surfaces (i.e., sidewalls) 236A and 236B of mandrel 218, and spacers 234A and 234B are formed on sidewalls 238A and 238B of mandrel 220. Each of spacers 232A, 232B, 234A, and 234B have substantially the same width SW. Spacers 232A, 232B, 234A, and 234B may be formed using known etching techniques, such as, but not limited to, an anisotropic etching process.

As shown in FIG. 2G, because mandrel 220 is formed such that it has a length and width extending along a direction that is non-perpendicular and non-parallel to long axis 250 and short axis 252 of fin(s) 202D-202F, spacers 234A and 234B are also formed such that each has a length and width that extends along a direction that is non-perpendicular and non-parallel to long axis 250 and short axis 252 of fin(s) 202D-202F. Accordingly, the widths of spacers 234A and 234B over a region corresponding to underlying fins 202D-202F along long axis 250 is longer than the widths of spacers 232A and 232B over a region corresponding to underlying fin(s) 202A-202C along long axis 250. That is, spacers 234A and 234B have a width SW2_{long}_{_}ₐₓᵢₛ over the region corresponding to underlying fin(s) 202D-202F along long axis 250, and spacers 232A and 232B have a width SW1_{long}_{_}ₐₓᵢₛ over the region corresponding to underlying fin(s) 202A-202C over long axis 250, where SW2_{long}_{_}ₐₓᵢₛ is longer than SW1_{long}_{_}ₐₓᵢₛ.

Next, as shown in FIGS. 2I and 2J, mandrels 218 and 220 are selectively removed, thereby leaving spacers 232A, 232B, 234A, and 234B (dummy gate stack layer 212 and hardmask layer 214 are rendered transparent in FIG. 2I for ease of illustration). Spacers 232A, 232B, 234A, and 234B collectively define a patterned spacer mask layer that is used to pattern hardmask layer 214 and dummy gate stack layer 212. Mandrels 218 and 220 may be removed using known photolithography and/or etching techniques.

Next, as shown in FIG. 2K, spacers 232A, 232B, 234A, and 234B are used as an etch mask during an etching process, for example, RIE, that is performed on hardmask layer 214 and dummy gate stack layer 212. This etching process results in the formation of patterned hardmask layer 214A′ 214B′, 214C′, and 214D′ and patterned dummy gate stack layer 212A′ 212B′, 212C′, and 212D′.

Next, as shown in FIGS. 2L and 2M, after forming patterned hardmask layer 214A′-214D′ and patterned dummy gate stack layer 212A′-214D′, spacers 232A, 232B, 234A, and 234B are removed, for example, by using known etching techniques. Patterned dummy gate stack layer 212A′ and patterned hardmask layer 214A′ collectively form gate 238, patterned dummy gate stack layer 212B′ and patterned hardmask layer 214B′ collectively form gate 240, patterned dummy gate stack layer 212C′ and patterned hardmask layer 214C′ collectively form gate 242, and patterned dummy gate stack layer 212D′ and patterned hardmask layer 214D′ collectively form gate 244. As shown in FIGS. 2L and 2M, patterned hardmask layer 214C′ and 214D′ and patterned dummy gate stack layer 212C′ and 212D′ extend along a direction that is non-perpendicular and non-parallel to long axis 250 and short axis 252 of fin(s) 202A-202F. Patterned dummy gate stack layer 212A′-212D′ is subsequently replaced by a high-k/metal gate dielectric material using a replacement metal gate (RMG) process in a subsequent manufacturing step, as is known to those ordinarily-skilled in the art.

Gates 238 and 240 are for a nominal finFET device 246, and gates 242 and 244 are for a wimpy finFET device 248. As shown in FIGS. 2L and 2M, gates 238 and 240 have a gate length of L1 (which is approximately the same as the width of spacers 232A and 232B (SW1_{long}) (as shown in FIG. 2G), and gates 242 and 244 have a gate length axis, of L2 (which is approximately the same as the width of spacers 234A and 234B over underlying fin(s) 202D-202F along long axis 250 (SW2_{long}_{_}ₐₓᵢₛ)), as shown in FIG. 2G), which is longer than L1. Additionally, as shown in FIG. 2M, nominal finFET device 246 has a gate pitch of P1, whereas wimpy finFET device 248 has a gate pitch of P2, which is longer than P1.

Accordingly, a wimpy finFET device may be fabricated by forming mandrel 220 that is non-perpendicular to long axis 250 and/or short axis 252 of underlying fin(s) 202D-202F (i.e., the mandrel is formed at a non-quadrantal angle) (as shown in FIGS. 2D and 2E). Spacers 234A and 234B formed on the sidewalls (i.e., first surface 238A and opposing second surface 238B) of mandrel 220 are thus also formed non-perpendicular to long axis 250 and/or short axis 252 of underlying fin(s) 202D-202F (as shown in FIGS. 2G and 2H). Spacers 234A and 234B are used to pattern hardmask layer 214 and dummy gate stack layer 212 down to underlying fin(s) 202D-202F (as shown in FIG. 2K). The resulting structures are gates 242 and 244 for wimpy finFET device 248. Because patterned hardmask layer 214C′ and 214D′ and patterned dummy gate stack layer 212C′ and 212D′ are also formed at a non-quadrantal angle, the width of patterned hardmask layer 214C′ and 214D′ and patterned dummy gate stack layer 212C′ and 212D′ is greater than would be if patterned hardmask layer 214C′ and 214D′ and patterned dummy gate stack layer 212C′ and 212D′ were formed at, for example, a right angle with respect to long axis 250. The greater width corresponds to greater gate length.

The desired gate length for gates 242 and 244 may be achieved by determining a non-quadrantal angle from a plurality of non-quadrantal angles at which mandrel 220 is formed. The desired gate length may be a function of the width of spacers (SW) and the angle at which mandrel 220 (which is the same angle at which spacers 234A and 234B) are formed. For example, the desired gate length may be determined in accordance with Equations 1 and 2, which are shown below:

SW2_{long}_{_}ₐₓᵢₛ=SW/cos(θ) (Equation 1)

θ=cos⁻¹(SW/SW2_{long}_{_}ₐₓᵢₛ) (Equation 2)

where θ corresponds to the angle (i.e., angle 226) at which mandrel 220 is formed with respect to long axis 250 of fin(s) 202D-202F (as shown in FIG. 2D). For example, if a gate length of 22 nm is desired and the width (SW) of spacers 234A and 234B is 18 nm, then the angle at which mandrel 220 is formed with respect to long axis 250 is 35 degrees. In another example, if a gate length of 25 nm is desired and the width (SW) of spacers 234A and 234B is 18 nm, then the angle at which mandrel 220 is formed with respect to long axis 250 is 45 degrees.

The desired gate-to-gate distance (or “gate pitch”) may also be achieved by determining the width (or thickness) at which mandrel 220 is formed. For example, with reference to FIG. 2M, suppose the gate length of gates 242 and 244 is 22 nm. If a gate pitch of 48 nm is desired, then mandrel 220 (as shown in FIGS. 2D and 2E) may be formed with a width (MW2) of 26 nm. On the other hand, if a gate pitch of 64 nm is desired, then mandrel 220 may be formed with a width (MW2) of 42 nm.

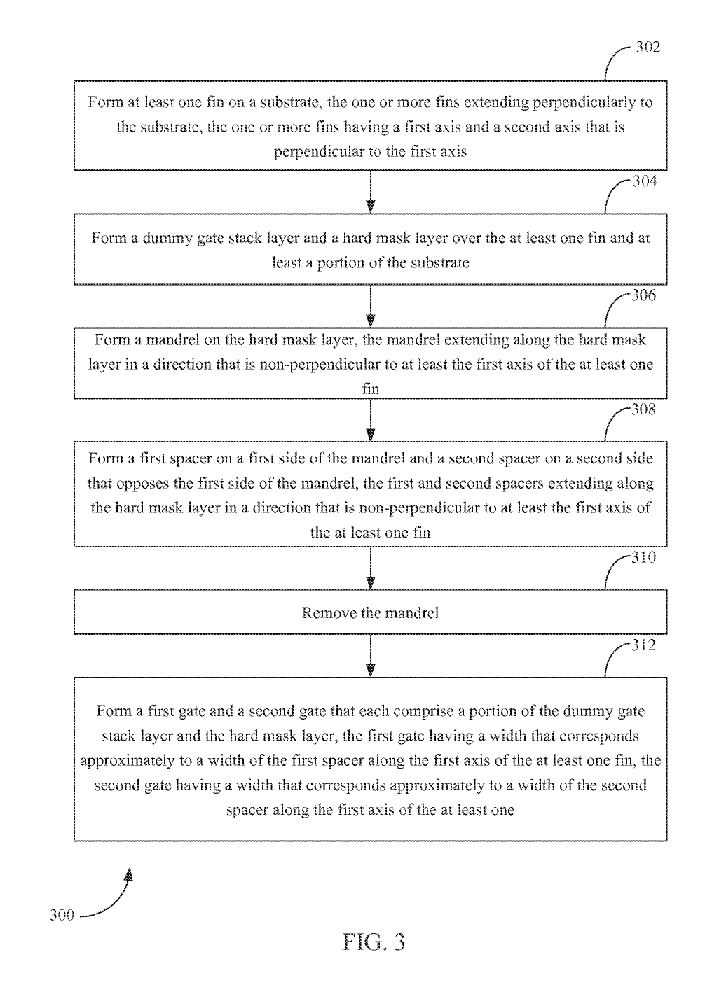

Accordingly, a wimpy finFET device may be fabricated in various ways. For instance, FIG. 3 shows a flowchart 300 providing an example process for fabricating a wimpy finFET device in accordance with an embodiment. For instance, wimpy finFET device 248 (as shown in FIGS. 2L and 2M) may be fabricating according to flowchart 300. Other structural and operational embodiments will be apparent to persons skilled in the relevant art(s) based on the discussion regarding flowchart 300. Flowchart 300 is described as follows.

As shown in FIG. 3, at least one fin on a substrate is formed (302). The at least one fin extends perpendicularly from a surface of the substrate, and the at least one fin has a first axis and a second axis that is perpendicular to the first axis. For example, with reference to FIGS. 2A and 2B, each of fin(s) 202D-202F are formed on substrate 204 and extend perpendicularly from surface 210 of substrate 204. As shown in FIG. 2D, each of fin(s) 202D-202F have a first axis (e.g., long axis 250) and a second axis (e.g., short axis 252) that is perpendicular to the first axis. The at least one fin may be formed using known deposition, photolithography and/or etching tools and techniques.

The at least one fin may be comprised of silicon or a silicon-based material, such as, but not limited to, silicon-germanium. Alternatively, the at least one fin may be comprised of other elementary semiconductors, such as, but not limited to, germanium, gallium arsenic, gallium phosphide, indium phosphide, indium arsenide, and/or indium antimonide.

The substrate may be comprised of silicon or a silicon-based material. In accordance with an embodiment, the substrate is a silicon-on-insulator (SOI) substrate. In accordance with such an embodiment, the substrate is comprised of silicon-based material, such as, but not limited to, silicon dioxide. In accordance with another embodiment, the substrate is a bulk substrate. In accordance with such an embodiment, the substrate is comprised of silicon. The substrate may be of any shape, including, but not limited to, rectangular, circular, square, etc.

Continuing with flowchart 300, a dummy gate stack layer and a hardmask layer are formed over the at least one fin and at least a portion of substrate (304). For example, with reference to FIG. 2C, dummy gate stack layer 212 and hardmask layer 214 are formed over each of fin(s) 202D-202F and substrate 204.

The dummy gate stack layer may be comprised of a silicon-based material, such as, but not limited to, polysilicon. The dummy gate stack layer may be formed using known deposition, photolithography and/or etching tools and techniques.

The hardmask layer may serve to protect the dummy gate stack layer during subsequent patterning steps performed for mandrel formation. The hardmask layer may be comprised of a silicon-based material, such as, but not limited to, silicon nitride, or other materials, such as, but not limited to, hafnium oxide or tantalum nitride. The hardmask layer may be formed using known deposition techniques, such as, but not limited to chemical vapor deposition (CVD).

Continuing with flowchart 300, a mandrel is formed on the hardmask layer (306). The mandrel extends along the hardmask layer in a direction that is non-perpendicular to at least the first axis of the at least one fin. For example, with reference to FIGS. 2D and 2E, mandrel 220 is formed on hardmask layer 214. Mandrel 220 extends along hardmask layer 214 in a direction that is non-perpendicular to at least the first axis (e.g., long axis 250) of each of fin(s) 202D-202F.

In accordance with one or more embodiments, the mandrel also extends along the hardmask layer in a direction that is non-perpendicular to a second axis (e.g., short axis 252) of each of fin(s) 202D-202F. For example, with reference to FIGS. 2D and 2E, mandrel 220 extends along hardmask layer 214 in a direction that is non-perpendicular to the second axis (e.g., short axis 252) of each fin(s) 202D-202F.

Continuing with flowchart 300, a first spacer is formed on a first side of the mandrel and a second spacer is formed on a second side of the mandrel that opposes the first side (308). The first and second spacers extend along the hardmask layer in a direction that is non-perpendicular to at least the first axis of the at least one fin. For example, with reference to FIGS. 2G and 2H, a first spacer 234A is formed on a first side 238A of mandrel 220, and a second spacer 234B is formed on a second side 238B of mandrel 220 that opposes first side 238A. Spacers 234A and 234B extend along hardmask layer 214 in a direction that is non-perpendicular to at least the first axis (e.g., long axis 250) of each of fin(s) 202D-202F.

Continuing with flowchart 300, the mandrel is removed (310). For example, with reference to FIGS. 2I and 2J, mandrel 220 is removed. Mandrel 220 may be removed using known photolithography and/or etching techniques.

Continuing with flowchart 300, a first gate and a second gate are formed that each comprise a portion of the dummy gate stack layer and the hardmask layer (312). The first gate has a gate length that corresponds approximately to a width of the first spacer along the first axis of the at least one fin, and the second gate has a gate length that corresponds approximately to a width of the second spacer along the first axis of the at least one fin. For example, with reference to FIGS. 2L and 2M, gate 242 and gate 244 are formed. Gate 242 comprises a first portion of hardmask layer 214 and dummy gate stack layer 212 (i.e., patterned hardmask layer 214C′ and patterned dummy gate stack layer 212C′), and gate 244 comprises a second portion of hardmask layer 214 and dummy gate stack layer 212 (i.e., patterned hardmask layer 214D′ and patterned dummy gate stack layer 212D′). As shown in FIGS. 2G, 2H, 2L, and 2M, the gate length (L2) of gate 242 corresponds approximately to a width (SW2long_axis) of first spacer 234A along the first axis (e.g., long axis 250) of fin(s) 202D-202F, and the gate length (L2) of gate 244 corresponds approximately to a width (SW2long_axis) of second spacer 234B along the first axis (e.g., long axis 250) of fin(s) 202D-202F.

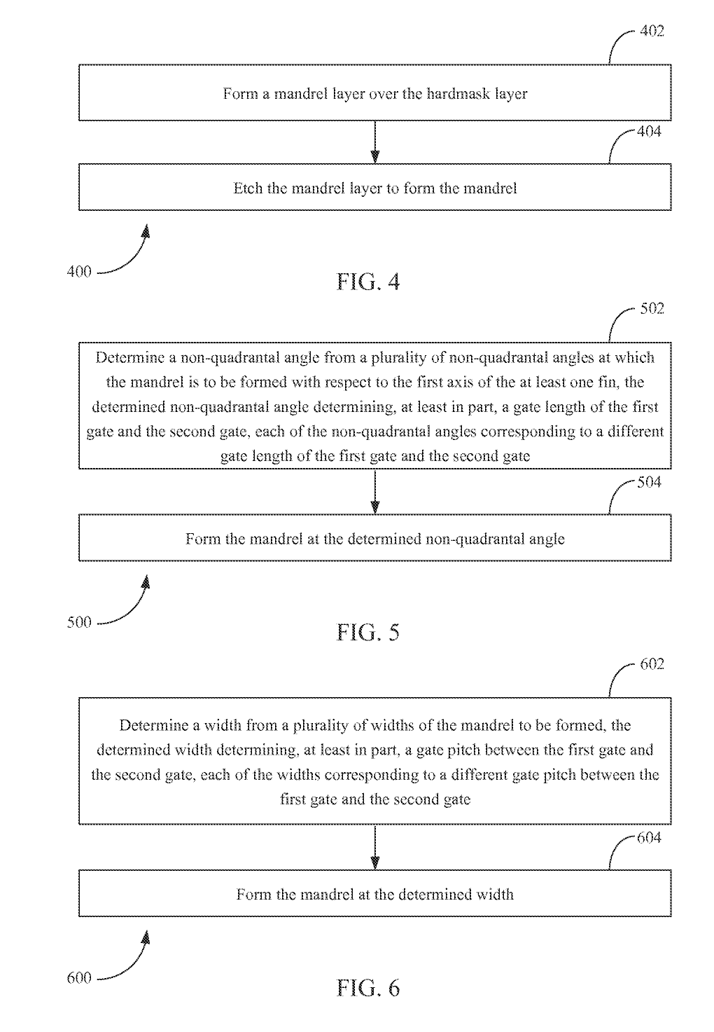

In accordance with one or more embodiments, step 306 of flowchart 300 may be carried out according to the process shown in FIG. 4. Other structural and operational embodiments will be apparent to persons skilled in the relevant art(s) based on the discussion regarding flowchart 400. Flowchart 400 is described as follows.

As shown in FIG. 4, a mandrel layer is formed over a hardmask layer (402). For example, with reference to FIG. 2C, mandrel layer 216 is formed over hardmask layer 214. The mandrel layer may be comprised of a silicon-based material, such as, but not limited to, amorphous silicon, polysilicon, silicon dioxide, etc., or other materials, such as, but not limited to, hafnium oxide or tantalum nitride. The mandrel layer may be formed using known deposition techniques, such as, but not limited to, CVD or physical vapor deposition (PVD).

Continuing with flowchart 400, the mandrel layer is etched to form the mandrel (404). For example, with reference to FIGS. 2D and 2E, mandrel layer 216 is etched to form mandrel 220. The mandrel layer may be etched to form the at least one mandrel using photolithography (e.g., e-beam lithography) and/or etching (e.g., reactive-ion etching (RIE)).

In accordance with one or more embodiments, step 306 of flowchart 300 may be carried out according to the process shown in FIG. 5. Other structural and operational embodiments will be apparent to persons skilled in the relevant art(s) based on the discussion regarding flowchart 500. Flowchart 500 is described as follows.

As shown in FIG. 5, a non-quadrantal angle from a plurality of non-quadrantal angles at which the mandrel is to be formed with respect to the first axis of the at least one fin is determined (502). The determined non-quadrantal angle determines, at least in part, a gate length of the first gate and the second gate. Each of the non-quadrantal angles corresponds to a different gate length of the first gate and the second gate. For example, with reference to FIG. 2D, mandrel 220 is formed by determining a non-quadrantal angle (e.g., 35 degrees) from a plurality of non-quadrantal angles at which mandrel 220 is to be formed with respect to the first axis (e.g., long axis 250) of fin(s) 202D-202F. As shown in FIGS. 2L and 2M, the gate length (L2) of gate 242 and gate 244 is determined by the determined non-quadrantal angle (along with the width (SW) of spacers 234A and 234B used to form gate 242 and gate 244 (as shown in FIGS. 2G and 2H)). The gate length of gate 242 and gate 244 decreases as the determined non-quadrantal angle increases, and the gate length of gate 242 and gate 244 increases, as the determined non-quadrantal angle decreases. In accordance with an embodiment, the gate length of gate 242 and gate 244 is determined in accordance with Equations 1 and 2 as described above.

Continuing with flowchart 500, the mandrel is formed at the determined non-quadrantal angle (504). For example, with reference to FIG. 2D, mandrel 220 is formed at the determined non-quadrantal angle.

In accordance with one or more embodiments, step 306 of flowchart 300 may be carried out according to the process shown in FIG. 6. Other structural and operational embodiments will be apparent to persons skilled in the relevant art(s) based on the discussion regarding flowchart 600. Flowchart 600 is described as follows.

As shown in FIG. 6, a width from a plurality of widths of the mandrel is determined (602). The determined width determines, at least in part, a gate pitch between the first gate and the second gate. Each of the widths corresponds to a different gate pitch between the first gate and the second gate. For example, with reference to FIG. 2M, the gate pitch (P2) between gates 242 and 244 may be determined, at least in part, by, determining a width from a plurality of widths of mandrel 220 to be formed, where the gate pitch (P2) becomes longer as mandrel 220 is formed with a longer width and becomes shorter as mandrel 220 is formed with a shorter width.

Continuing with flowchart 600, the mandrel is formed at the determined width (604). For example, with reference to FIG. 2D, mandrel 220 is formed at the determined width.

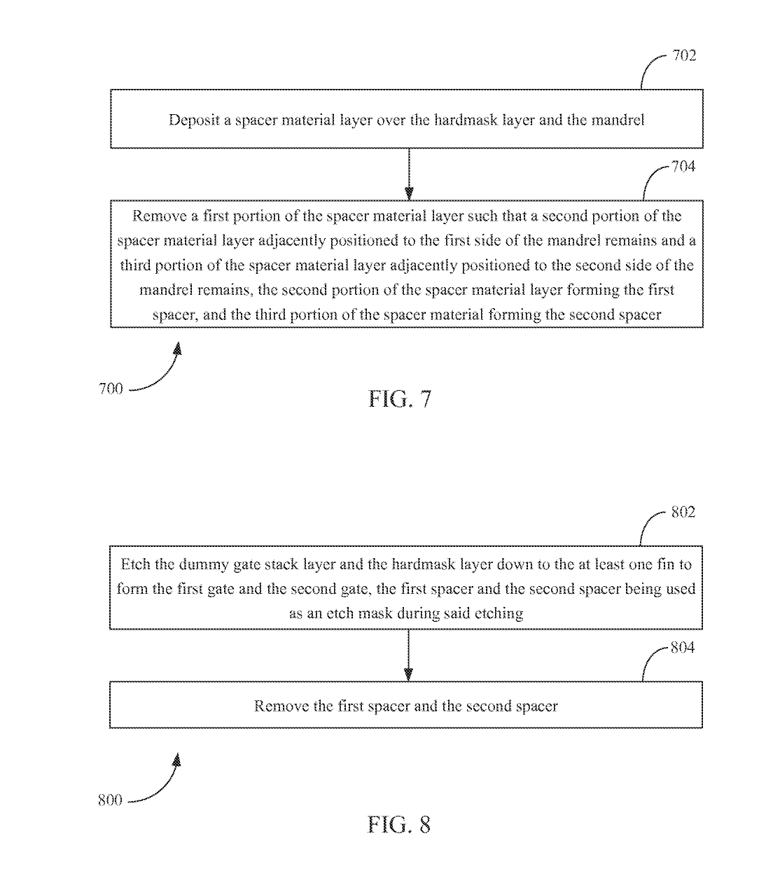

In accordance with one or more embodiments, step 308 of flowchart 300 may be carried out according to the process shown in FIG. 7. Other structural and operational embodiments will be apparent to persons skilled in the relevant art(s) based on the discussion regarding flowchart 700. Flowchart 700 is described as follows.

As shown in FIG. 7, a spacer material layer is deposited over the hardmask layer and the mandrel (702). For example, with reference to FIG. 2F, spacer material layer 230 is deposited over hardmask layer 214 and mandrel 220 with a uniform thickness T. Spacer material layer 230 may be comprised of a silicon-based material, such as, but not limited to, silicon nitride, silicon dioxide, etc. Spacer material layer 230 may be formed using known deposition techniques.

Continuing with flowchart 700, a first portion of the spacer material layer is removed such that a second portion of the spacer material layer adjacently positioned to the first side of the mandrel remains and a third portion of the spacer material layer adjacently positioned to the second side of the mandrel remains (704). The second portion of the spacer material layer forms the first spacer, and the third portion of the spacer material layer forms the second spacer. For example, with reference to FIGS. 2G and 2H, a first portion of spacer material layer 230 is removed such that a second portion of spacer material layer 230 (i.e., spacer 238A) adjacently positioned to first side 238A of mandrel 220 remains and a third portion of spacer material layer (i.e., spacer 238B) adjacently positioned to second side 238B of mandrel 220 remains. Spacers 234A and 234B may be formed using known etching techniques, such as, but not limited to, an anisotropic etching process.

In accordance with one or more embodiments, step 312 of flowchart 300 may be carried out according to the process shown in FIG. 8. Other structural and operational embodiments will be apparent to persons skilled in the relevant art(s) based on the discussion regarding flowchart 800. Flowchart 800 is described as follows.

As shown in FIG. 8, the hardmask layer and the dummy gate stack layer are etched down to the at least one fin to form the first gate and the second gate, the first spacer and the second spacer being used as an etch mask during said etching (802). For example, with reference to FIG. 2K, first spacer 234A and second spacer 234B are used as an etch mask during an etching process that etches hardmask layer 214 and dummy gate stack layer 212 down to each of fin(s) 202D-202F to respectively form patterned hardmask layer 214C′ and 214D′ and patterned dummy gate stack layer 212C′ and 212D′.

Continuing with flowchart 800, the first spacer and the second spacer are removed (804). As shown in FIGS. 2L and 2M, after the etching process is completed, spacers 234A and 234B are removed. Spacers 234A and 234B are removed, for example, by using known etching techniques, such as RIE.

It is noted that while the foregoing embodiments describe that a mandrel formed non-perpendicularly to the long axes of underlying fin(s) can be used for fabricating a wimpy finFET device and that a mandrel formed perpendicularly to the long axes of the underlying fin(s) can be used for fabricating a nominal finFET device, in accordance with one or more embodiments, a mandrel formed non-perpendicularly to the long axes of underlying fin(s) can be used for fabricating a nominal finFET device and a mandrel formed perpendicularly to the long axes of the underlying fin(s) can be used for fabricating a wimpy finFET device.

### IV. CONCLUSION

While various embodiments have been described above, it should be understood that they have been presented by way of example only, and not limitation. It will be apparent to persons skilled in the relevant art that various changes in form and detail can be made therein without departing from the spirit and scope of the embodiments. Thus, the breadth and scope of the embodiments should not be limited by any of the above-described exemplary embodiments, but should be defined only in accordance with the following claims and their equivalents.

1-10. (canceled)

11. A semiconductor device, comprising:
one or more first fins on a substrate, each fin of the one or more first fins extending perpendicularly from a surface of the substrate, each fin of the one or more first fins having a first axis and a second axis that is perpendicular to the first axis;
one or more second fins on the substrate, each fin of the one or more second fins extending perpendicularly from the surface of the substrate, each fin of the one or more second fins having a third axis parallel to the first axis and a fourth axis that is parallel to the second axis;
a wimpy semiconductor device, comprising:
a first gate and a second gate that each comprise a dummy gate stack layer and a hardmask layer formed over each fin of the one or more first fins, the dummy gate stack layer and the hardmask layer extending along each fin of the one or more first fins in a direction that is non-perpendicular to at least the first axis of each fin of the one or more first fins and is non-perpendicular to at least the second axis of each fin of the one or more first fins, each of the first gate and the second gate comprising a fifth axis and a sixth axis that is perpendicular to the fifth axis; and
a nominal semiconductor device, comprising:
a third gate and a fourth gate formed over each fin of the one or more second fins, a gate length of the third gate and the fourth gate of the nominal semiconductor device being different than a gate length of the first gate and the second gate of the wimpy semiconductor device, each of the third gate and the fourth gate comprising a seventh axis and an eighth axis that is perpendicular to the seventh axis, each of the seventh axis and the eight axis of the third gate and the fourth gate being non-perpendicular to both of the fifth axis and the sixth axis of each of the first gate and the second gate.

12. The semiconductor device of claim 11, wherein the first gate has a gate length that corresponds approximately to a width of a first spacer that is used as an etch mask to form the first gate, and wherein the second gate has a gate length that corresponds approximately to a width of a second spacer that is used as an etch mask to form the second gate.

13. The semiconductor device of claim 11, wherein the dummy gate stack layer and the hardmask layer further extend along each fin of the one or more first fins in a direction that is non-parallel to at least the first axis of each fin of the one or more first fins and is non-parallel to at least the second axis of each fin of the one or more first fins.

14. The semiconductor device of claim 11, wherein the first axis is a long axis of each fin of the one or more first fins.

15. The semiconductor device of claim 11, wherein the second axis is a short axis of each fin of the one or more first fins.

16-20. (canceled)

21. The semiconductor device of claim 11, wherein the fifth axis is a short axis of the fifth gate and the sixth gate, and the seventh axis is a short axis of the seventh gate and the eight gate.

22. The semiconductor device of claim 11, wherein the sixth axis is a long axis of the fifth gate and the sixth gate, and the eight axis is a long axis of the seventh gate and the eight gate.

23. A semiconductor device, comprising:
a first plurality of fins on a substrate, each fin of the first plurality of fins extending perpendicularly from a surface of the substrate, each fin of the first plurality of fins having a first axis and a second axis that is perpendicular to the first axis;
a second plurality of fins on the substrate, each fin of the second plurality of fins extending perpendicularly from the surface of the substrate, each fin of the second plurality of fins having a third axis parallel to the first axis and a fourth axis that is parallel to the second axis;
a wimpy semiconductor device, comprising:
a first gate and a second gate that each comprise a dummy gate stack layer and a hardmask layer formed over each fin of the first plurality of fins, the dummy gate stack layer and the hardmask layer extending along each fin of the first plurality of fins in a direction that is non-perpendicular to at least the first axis of each fin of the first plurality of fins and is non-perpendicular to at least the second axis of each fin of the first plurality of fins, each of the first gate and the second gate comprising a fifth axis and a sixth axis that is perpendicular to the fifth axis; and
a nominal semiconductor device, comprising:
a third gate and a fourth gate formed over each fin of the second plurality of fins, a gate length of the third gate and the fourth gate of the nominal semiconductor device being different than a gate length of the first gate and the second gate of the wimpy semiconductor device, each of the third gate and the fourth gate comprising a seventh axis and an eighth axis that is perpendicular to the seventh axis, each of the seventh axis and the eight axis of the third gate and the fourth gate being non-perpendicular to both of the fifth axis and the sixth axis of each of the first gate and the second gate.

24. The semiconductor device of claim 23, wherein the first gate has a gate length that corresponds approximately to a width of a first spacer that is used as an etch mask to form the first gate, and wherein the second gate has a gate length that corresponds approximately to a width of a second spacer that is used as an etch mask to form the second gate.

25. The semiconductor device of claim 23, wherein the dummy gate stack layer and the hardmask layer further extend along each fin of the first plurality of fins in a direction that is non-parallel to at least the first axis of each fin of the first plurality of fins and is non-parallel to at least the second axis of each fin of the first plurality of fins.

26. The semiconductor device of claim 23, wherein the first axis is a long axis of each fin of the first plurality of fins.

27. The semiconductor device of claim 23, wherein the second axis is a short axis of each fin of the first plurality of fins.

28. The semiconductor device of claim 23, wherein the fifth axis is a short axis of the fifth gate and the sixth gate, and the seventh axis is a short axis of the seventh gate and the eight gate.

29. The semiconductor device of claim 23, wherein the sixth axis is a long axis of the fifth gate and the sixth gate, and the eight axis is a long axis of the seventh gate and the eight gate.

30. A semiconductor device, comprising:
one or more first cuboid-shaped fins on a substrate, each fin of the one or more first cuboid-shaped fins extending perpendicularly from a surface of the substrate, each fin of the one or more first cuboid-shaped fins having a first axis and a second axis that is perpendicular to the first axis;
one or more second cuboid-shaped fins on the substrate, each fin of the one or more second cuboid-shaped fins extending perpendicularly from the surface of the substrate, each fin of the one or more second cuboid-shaped fins having a third axis parallel to the first axis and a fourth axis that is parallel to the second axis;
a wimpy semiconductor device, comprising:
a first gate and a second gate that each comprise a dummy gate stack layer and a hardmask layer formed over each fin of the one or more first cuboid-shaped fins, the dummy gate stack layer and the hardmask layer extending along each fin of the one or more first cuboid-shaped fins in a direction that is non-perpendicular to at least the first axis of each fin of the one or more first cuboid-shaped fins and is non-perpendicular to at least the second axis of each fin of the one or more first cuboid-shaped fins, each of the first gate and the second gate comprising a fifth axis and a sixth axis that is perpendicular to the fifth axis; and
a nominal semiconductor device, comprising:
a third gate and a fourth gate formed over each fin of the one or more second cuboid-shaped fins, a gate length of the third gate and the fourth gate of the nominal semiconductor device being different than a gate length of the first gate and the second gate of the wimpy semiconductor device, each of the third gate and the fourth gate comprising a seventh axis and an eighth axis that is perpendicular to the seventh axis, each of the seventh axis and the eight axis of the third gate and the fourth gate being non-perpendicular to both of the fifth axis and the sixth axis of each of the first gate and the second gate.

31. The semiconductor device of claim 30, wherein the first gate has a gate length that corresponds approximately to a width of a first spacer that is used as an etch mask to form the first gate, and wherein the second gate has a gate length that corresponds approximately to a width of a second spacer that is used as an etch mask to form the second gate.

32. The semiconductor device of claim 30, wherein the dummy gate stack layer and the hardmask layer further extend along each fin of the one or more first cuboid-shaped fins in a direction that is non-parallel to at least the first axis of each fin of the one or more first cuboid-shaped fins and is non-parallel to at least the second axis of each fin of the one or more first cuboid-shaped fins.

33. The semiconductor device of claim 30, wherein the first axis is a long axis of each fin of the one or more first cuboid-shaped fins.

34. The semiconductor device of claim 30, wherein the second axis is a short axis of each fin of the one or more first cuboid-shaped fins.

35. The semiconductor device of claim 30, wherein the fifth axis is a short axis of the fifth gate and the sixth gate, and the seventh axis is a short axis of the seventh gate and the eight gate.
